(19) United States
(12) Patent Application Publication
(10) Pub. No.: US 2005/0277255 A1
(43) Pub. Date: Dec. 15, 2005

(54) Compound semiconductor device and manufacturing method thereof

(75) Inventor: Tetsuro Asano, Ora-gun (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/150,471

(22) Filed: Jun. 13, 2005

(30) Foreign Application Priority Data
Jun. 14, 2004 (JP) 2004-175700

(51) Int. Cl. H01L 21/338; H01L 31/0328; H01L 31/0336; H01L 31/072; H01L 31/109; H01L 21/336

(52) U.S. Cl. 438/285; 438/172; 257/192

(57) ABSTRACT

A pad electrode of a high electron mobility transistor is formed solely of a pad metal layer without providing a gate metal layer. A high concentration impurity region is provided below the pad electrode, and the pad electrode is directly contacted to a substrate. Predetermined isolation is ensured by the high concentration impurity region. Accordingly, in a structure not requiring a nitride film as similar to the conventional art, it is possible to avoid defects upon wire boding attributing to hardening of the gate metal layer. Therefore, even in the case of a buried gate electrode structure for enhancing characteristics of the high electron mobility transistor, it is possible to enhance reliability and yields.

### BACKGROUND OF THE INVENTION

1. Field of the Invention

The present invention relates to a compound semiconductor device and a manufacturing method of the same, particularly, to a compound semiconductor device and a manufacturing method of the same which are capable of enhancing characteristics of field effect transistors and reducing defects in wire bonding.

2. Background Art

Mobile communication devices such as mobile telephones often use microwaves in a gigahertz range and frequently use switching devices to switch antennas or transmitting/receiving for switching those high frequency signals (see Japanese Patent Application Publication No. Hei 9-181642, for example). Such devices often use field effect transistors (hereinafter referred to as FETs) using gallium arsenide (GaAs) to deal with microwave signals. In this concern, development of monolithic microwave integrated circuits (MMICs) configured to integrate the above-mentioned switching circuits are now in progress.

FIG. 9 is a schematic circuit diagram showing a principle of a compound semiconductor switching circuit called SPDT (single pole double throw) which uses FETs.

Here, sources (or drains) of first and second field effect transistors FET1 and FET2 are connected to common input terminal IN, and gates of the field effect transistors FET1 and FET2 are connected to first and second control terminals Ctl-1 and Ctl-2 through resistors R1 and R2, respectively. Moreover, drains (or sources) of the FETs are connected to first and second output terminals OUT1 and OUT2, respectively. Signals applied to the first and second control terminals Ctl-1 and Ctl-2 are complementary signals, and the FET to which a H-level signal is applied is turned ON to transmit a high frequency signal entered to the input terminal IN to one of the output terminals. The resistors R1 and R2 are disposed in order to prevent leakage of high frequency signals through the gate electrodes with respect to direct current potential at the control terminals Ctl-1 and Ctl-2, which is a AC ground potential.

A GaAs substrate is semi-insulating. However, in the case of integrating a switching circuit on the GaAs substrate, if a pad electrode layer for wire bonding is provided directly on the substrate, an electric interaction will remain between adjacent electrodes. Such an aspect may cause a lot of problems such as occurrence of damages by electrostatic discharge due to low insulation strength or deterioration in isolation due to leakage of a high frequency signal. Accordingly, a nitride film has been provided below a wiring layer or below pad electrodes in a conventional manufacturing method.

However, the nitride film is hard and therefore causes cracks on pad portions by pressure at the time of bonding. To suppress such cracks, gold plating has been applied to bonding electrodes on the nitride film. However, a gold plating process causes increases in the number of processes and in costs. Therefore, a technique for avoiding provision of the nitride film below the pad electrodes has been developed.

An example of a method of manufacturing FETs, pads, and wirings collectively constituting the conventional compound semiconductor switching circuit shown in FIG. 9 will be described with reference to FIG. 10A to FIG. 12B.

Firstly, as shown in FIG. 10A, buffer layer 41 in a thickness of about 6000 Å is formed on undoped initial compound semiconductor substrate 51 made of GaAs or the like, and n-type epitaxial layer 42 is grown thereon. Thereafter, the entire surface of the resultant structure is covered with silicon nitride film 53 for annealing in a thickness from about 500 Å to 600 Å.

Resist layer 54 is provided on the entire surface, and then a lithography process is performed to selectively form openings of this resist layer 54 in positions corresponding to a source region, a drain region, a gate wiring, and pad electrodes. Subsequently, ions of an impurity (²⁹Si⁺) are implanted to provide an n-type while using this resist layer 54 as a mask. In this way, n⁺-type source region 56 and drain region 57 are formed and high concentration impurity regions 60 are also formed on a surface of the n-type epitaxial layer 42 below the regions for forming the pad electrodes and the gate wiring. Since it is possible to ensure isolation by these high concentration impurity regions 60, it is possible to eliminate a nitride film which has been conventionally provided for the purpose of isolation.

If the nitride film is not required, it is not necessary to consider a risk of cracks on the nitride film at the time of bonding of a bonding wire. Accordingly, it is possible to omit the gold plating process which has been conventionally required. The gold plating process causes increases in the number of processes and in costs. Therefore, if it is possible to omit this process, such a technique can contribute largely to simplification of the manufacturing process and to cost reduction.

In FIG. 10B, new resist layer 58 is provided on the entire surface of the silicon nitride film 53, and a lithography process is performed to selectively leave the resist layer 58 at portions above operating region 18 of a FET and above the high concentration impurity portions 60 below gate wiring 62 and below the pad electrodes, and to form openings for the rest of portions. Subsequently, ions of an impurity (B⁺ or H⁺) are implanted while using this resist layer 58 as a mask, and then activation annealing is performed after removing the resist layer 58. In this way, the source and drain regions 56 and 57 and the high concentration impurity regions 60 are activated, thereby forming insulating region 45 reaching the buffer layer 41.

In FIG. 11A, firstly, the photolithography process for selectively forming the openings for formation regions for first source electrode 65 and first drain electrode 66 is performed, and then the silicon nitride film 53 is removed. Subsequently, three layers of AuGe/Ni/Au to be ohmic metal layer 64 are sequentially deposited by vacuum evaporation.

Thereafter, the first source electrode 65 and the first drain electrode 66 are formed by lift-off and alloy methods.

Next, in FIG. 11B, the photolithography process for selectively forming the openings for formation regions for gate electrode 69, first pad electrode 91, and the gate wiring 62 is performed. The silicon nitride film 53 exposed for the formation regions for the gate electrode 69, the first pad electrode 91, and the gate wiring 62 is subjected to dry etching, thereby exposing channel layer 52 in the forming region for the gate electrode 69 and exposing GaAs in the formation regions for the gate wiring 62 and the first pad electrode 91.

Thereafter, metal films of Pt/Ti/Pt/Au collectively to be a gate metal layer as a second metal layer are sequentially deposited by vacuum evaporation. Then, the resist layer is removed and the gate electrode 69 contacting the channel layer 52, the first pad electrode 91, and the gate wiring 62 are formed by the lift-off method.

Thereafter, a heat treatment for burying Pt is performed, and part of the gate electrode 69 is thereby buried into the channel layer 52. The FET having the Pt-buried gate has lower ON resistance value, higher breakdown voltage, and superior electric characteristics as compared to a FET having a Ti/Pt/Au gate.

In FIG. 12A, the surface of the substrate 51 is covered with passivation film 72 made of a silicon nitride film. The photolithography process is performed on this passivation film 72 to form contact holes for the first source electrode 65, the first drain electrode 66, the gate electrode 69, and the first pad electrode 91, and then the resist layer is removed.

Thereafter, a new resist layer is coated on the entire surface of the substrate 51, and a photolithography process for selectively forming openings in the resist for formation regions for second source electrode 75, second drain electrode 76, and second pad electrode 92 is performed. Subsequently, three layers of Ti/Pt/Au to be a pad metal layer as a third metal layer are sequentially deposited by vacuum evaporation, and the second source electrode 75, the second drain electrode 76, and the second pad electrode 92 are formed so as to contact the first source electrode 65, the first drain electrode 66, and the first pad electrode 91, respectively. Here, part of wiring portions are formed by use of this pad metal layer, the pad metal layer corresponding to the wiring portions are naturally left over.

Then, as shown in FIG. 12B, bonding wire 80 is bonded onto the second pad electrode 92. This technology is described for instance in Japanese Patent Application Publication No. 2003-007725.

As described above, the high concentration impurity regions 60 are provided below the pad electrode 91 and 92 and below the gate wiring 62 so as to protrude out of these regions. In this way, it is possible to suppress depletion layers extending from the pad electrodes 91 and 92 and the gate wiring 62 toward the substrate. Therefore, sufficient isolation can be ensured even when the pad electrodes 91 and 92 and the gate wiring 62 are provided directly on the GaAs substrate. Accordingly, it is possible to remove the nitride film which has been conventionally provided for the purpose of insulation.

When the nitride film is not required, it is not necessary to consider cracks of the nitride film at the time of bonding of the bonding wire. Therefore, it is possible to omit the gold plating process which has been conventionally required. The gold plating process causes increases in the number of processes and in costs. That is, if it is possible to omit this process, such a technique can contribute largely to simplification of the manufacturing process and to cost reduction.

However, it is made clear that many problems occur at the time of bonding of the bonding wire when part of the gate electrode 69 was buried in the channel layer 52 to enhance characteristics of the FET as shown in FIG. 11B.

Part of the first pad electrode 91 made of gate metal layer 68 is also buried in the surface of the substrate in the course of the process to bury the gate electrode 69. That is, the problem is considered due to formation of a hard alloy layer as a result of a reaction of Pt of the lowermost layer of the first pad electrode 91 to Ga or As contained in the material for the substrate.

For this reason, problems such as degradation in bonding adhesion or gouges on the substrate occur and lead to reduction in yields or deterioration in reliability.

### SUMMARY OF THE INVENTION

The present invention provides a compound semiconductor device that includes a compound semiconductor substrate, a stack of semiconductor layers disposed on the substrate, an operating region formed in the stack, a source region and a drain region that are formed in the operating region, a gate electrode made of a gate metal layer and in contact with the operating region, a source electrode comprising a first source electrode made of an ohmic metal layer and in contact with the source region and a second source electrode made of a pad metal layer and disposed on the first source electrode, a drain electrode comprising a first drain electrode made of the ohmic metal layer and in contact with the drain region and a second drain electrode made of the pad metal layer and disposed on the first drain electrode, a pad electrode made of the pad metal layer and in contact with the stack, and a conducting region formed in the stack and adjacent the pad electrode.

The present invention also provides a method of manufacturing a compound semiconductor device that includes providing a compound semiconductor substrate, forming a stack of semiconductor layers on the substrate, forming a conducting region and an operating region in the stack, forming a gate electrode made of a first metal on the operating region, forming a pad electrode made of a second metal so that the second metal is in contact with the stack, the pad electrode being adjacent the conducting region, and bonding a bonding wire to the pad electrode.

The present invention further provides a method of manufacturing a compound semiconductor device that includes providing a compound semiconductor substrate, forming a stack of semiconductor layers on the substrate, forming a conducting region and an operating region in the stack, depositing a first metal layer on the stack so as to form a first source electrode and a first drain electrode in contact with the operating region, depositing a second metal layer on the stack so as to from a gate electrode on the operating region, depositing a third metal layer on the stack so as to form a second source electrode on the first source electrode, a second drain electrode on the first drain electrode and a pad electrode that is in contact with the stack and adjacent the conducting region, and bonding a bonding wire to the pad electrode.

### BRIEF DESCRIPTION OF THE DRAWINGS

FIG. 1A is a plan view and FIGS. 1B to 1D are cross-sectional view for describing a first embodiment of the present invention.

FIGS. 2A and 2B are cross-sectional views for describing the first embodiment of the present invention.

FIGS. 3A and 3B are cross-sectional views for describing the first embodiment of the present invention.

FIGS. 4A to 4D are cross-sectional views for describing the first embodiment of the present invention.

FIGS. 5A to 5C are cross-sectional views for describing the first embodiment of the present invention.

FIG. 6 is a cross-sectional view for describing a second embodiment of the present invention.

FIGS. 7A to 7D are cross-sectional views for describing the second embodiment of the present invention.

FIGS. 8A to 8C are cross-sectional views for describing the second embodiment of the present invention.

FIG. 9 is a circuit diagram for describing the conventional art.

FIGS. 10A and 10B are cross-sectional views for describing the conventional art.

FIGS. 11A and 11B are cross-sectional views for describing the conventional art.

FIGS. 12A and 12B are cross-sectional views for describing the conventional art.

### DESCRIPTION OF THE PREFERRED EMBODIMENTS

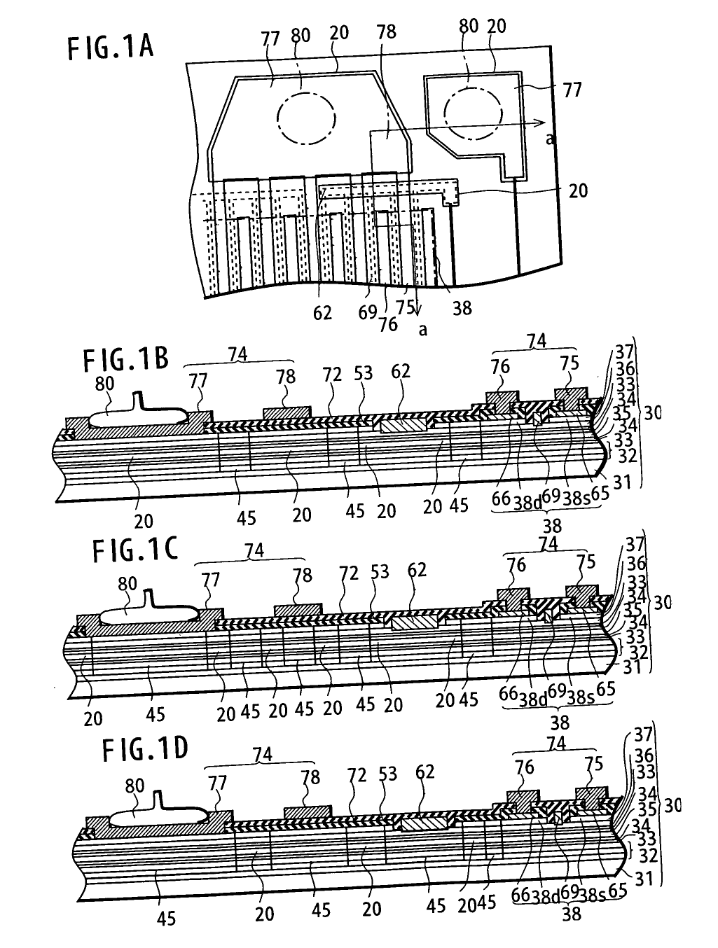

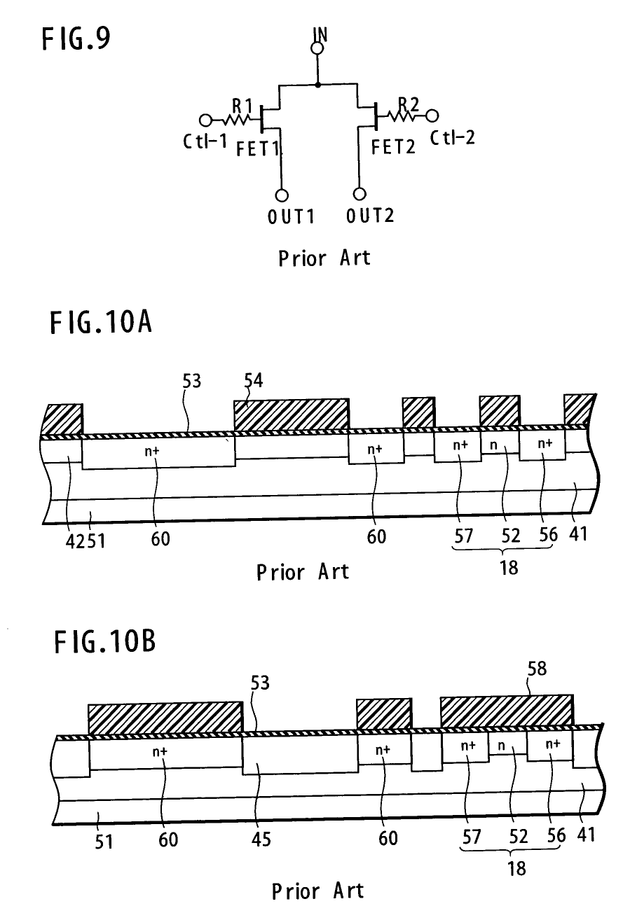

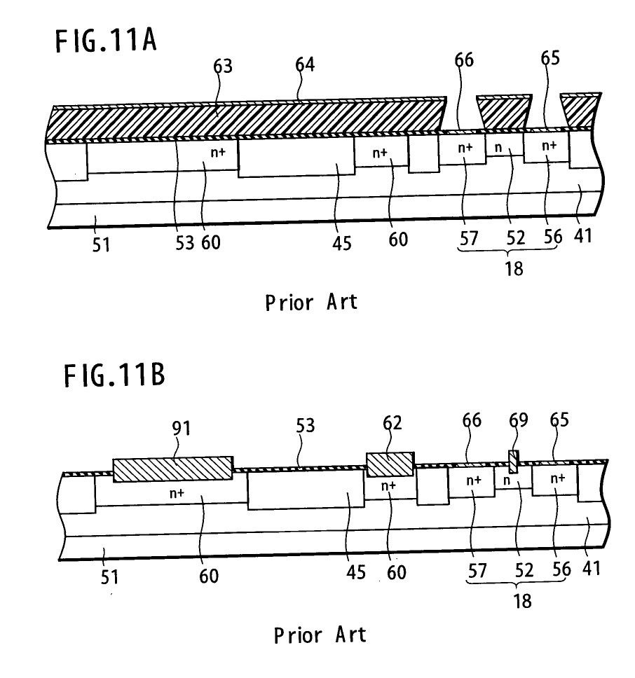

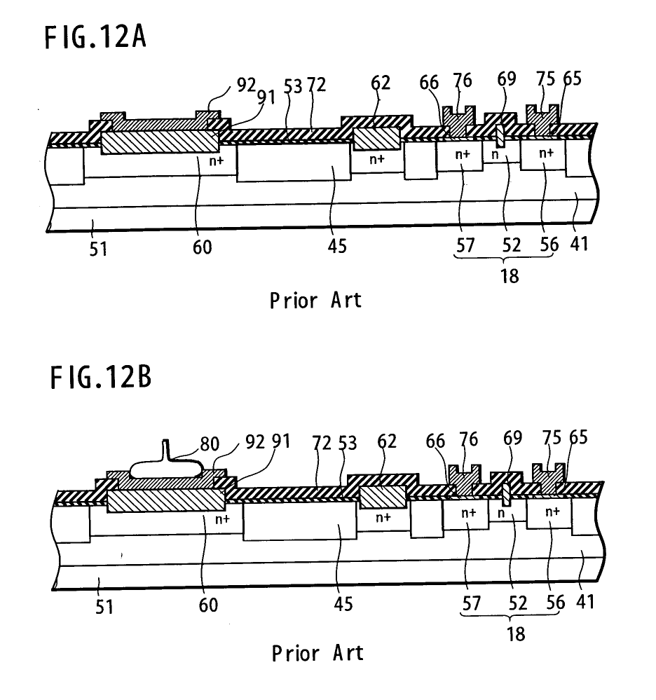

The preferred embodiments of the present invention will now be described with reference to FIG. 1A to FIG. 8C. The description concerning a high electron mobility transistor (HEMT), an electrode pad, and a wiring portion collectively constituting the switching circuit device (the SPDT) and the like shown in FIG. 9 as an example will be given.

FIGS. 1A to 1D are views showing an example of a compound semiconductor device of a first embodiment of the present invention, in which FIG. 1A is a plan view and FIG. 1B is a cross-sectional view taken along the a-a line. Here, the same formation elements as those in the conventional art are designated by the same reference numerals.

As shown in FIGS. 1A and 1B, concerning a method of forming substrate 30, first, undoped buffer layer 32 is grown on semi-insulating initial GaAs substrate 31. The buffer layer 32 is frequently formed as a plurality of layers. Then, n⁺-type AlGaAs layer 33 to be an electron supply layer, undoped InGaAs layer 35 to be an electron transimtting layer, and n⁺-type AlGaAs layer 33 to be another electron supply layer are sequentially grown on the buffer layer 32. Meanwhile, spacer layer 34 is disposed between the electron supply layer 33 and the electron transmitting layer 35.

Undoped AlGaAs layer 36 to be a barrier layer is grown on the electron supply layer 33 to ensure predetermined breakdown voltage and pinch-off voltage. Moreover, n⁺-type GaAs layer 37 to be a cap layer is grown in the uppermost layer. A metal layer such as a source electrode or a drain electrode is connected to the cap layer 37. By forming the cap layer 37 to have high impurity concentration, source resistance value or drain resistance value is reduced and an ohmic characteristic is thereby enhanced.

In the HEMT, electrons generated by a donor impurity in the n⁺-type AlGaAs layer 33 as the electron supply layer move toward the electron transmitting layer 35, whereby a channel functioning as a current path is formed. As a result, the electrons and donor ions are spatially isolated at a heterojunction interface as a boundary. Although the electrons transmit in the electron transimtting layer 35, there are no donor ions causing reduction in electron mobility in the electron transimtting layer 35. Accordingly, the electron transimtting layer 35 can retain high electron mobility.

Meanwhile, in the HEMT, necessary patterns are formed by isolating the substrate by use of insulating region 45 selectively formed in the substrate. Here, the insulating region 45 does not have electrically complete insulation characteristics, but is a region insulated by providing the epitaxial layer with a carrier trapping level by ion implantation of an impurity (B⁺).

Moreover, in this specification, when an element, a pad, and a wiring are adjacent to one another in an MMIC using the HEMT, an impurity region is provided for ensuring isolation therebetween. This impurity region is formed by designing and disposing a non-insulating region, that is, a region which is not subjected to the B⁺ ion implantation.

As shown in FIGS. 1A and 1B, first source electrode 65 and first drain electrode 66 made of an ohmic metal layer (AuGe/Ni/Au) of a first metal layer are provided on the cap layer 37 of the substrate in operating region 38 to be a source region 38s and a drain region 38d. Here, the operating region 38 is a region isolated by the insulating region 45 where the first source electrode 65 and a second source electrode 75, the first drain electrode 66 and a second drain electrode 76, and gate electrode 69 are disposed in comb-teeth shapes. Note that FIG. 1B shows one set of the source region 38s, the drain regions 38d, and the gate electrode 69. However, in reality, the operating region 38 is formed as indicated with dashed-dotted lines by means of arranging a plurality of sets adjacently to one another while using the source region 38s or the drain region 38d in common (see FIG. 1A).

Meanwhile, part of the operating region 38, that is, the cap layer 37 between the source region 38s and the drain region 38d is etched. Thereafter, a gate metal layer (Pt/Mo) of a second metal layer is evaporated to the exposed undoped AlGaAs layer 36 to form Schottky junction, thereby providing the gate electrode 69 and gate wiring 62.

In addition, the second source electrode 75 and the second drain electrode 76 made of a pad metal layer (Ti/CPt/Au) of a third metal layer are provided on the first source electrode 65 and the first drain electrode 66. The source electrode 75, the drain electrode 76, and the gate electrode 69 are arranged in the form of engaging comb teeth with one another, thereby constituting the HEMT.

Here, the gate electrode 69 constitutes a buried gate electrode where a part of the gate electrode 69 is buried in a part of the operating region 38 while maintaining the Schottky junction with the substrate.

By forming the buried gate electrode, an edge on the drain side of a cross section of the gate electrode 69 is formed into a round shape (and an edge on the source side as well), and electric field strength between the gate electrode and the drain electrode can be reduced. Accordingly, it is possible to increase breakdown voltage between the gate and the drain. On the contrary, in case the breakdown voltage is set to a predetermined value, it is possible to increase the donor impurity concentration of the n⁺-type AlGaAs layer 33 as the electron supply layer relevantly. As a result, the number of electrons flowing in the undoped InGaAs layer 35 as the electron transmitting layer is increased. In this way, there are advantages of substantially improving current density, channel resistance, and a high frequency distortion characteristic.

Pad electrode 77 is formed by directly contacting pad metal layer 74 extending from the operating region 38 of the HEMT to a surface of the substrate 30 (a surface of the cap layer 37). A high frequency analog signal is transmitted on the pad electrode 77. In the substrate 30 below the pad electrode 77, high concentration impurity region 20 is provided. The high concentration impurity region 20 is contacted directly to the entire surface of the pad electrode 77 such that a peripheral portion thereof protrudes out of the pad electrode 77. The high concentration impurity region 20 is formed by isolation by use of the insulating region 45.

Here, the high concentration impurity region 20 is a region having impurity concentration equal to or above 1×10¹⁷ cm⁻³. In the case of FIG. 1B, the structure of the high concentration impurity region 20 is the same as the epitaxial structure of the HEMT. However, due to inclusion of the cap layer 37 (having impurity concentration around 1 to 5×10¹⁸ cm⁻³), the region functions as the high concentration impurity region. Meanwhile, the high concentration impurity region 20 is connected to the pad electrode 77 in direct current mode.

If a metal layer, such as the pad electrode 77, functioning as a high frequency signal path is directly provided on a semi-insulating substrate, a depletion layer reaches an adjacent electrode or wiring due to variation in a distance of the depletion layer in response to a high frequency signal. Leakage of a high frequency signal occurs in a space between metal layers where the depletion layer reaches.

However, by providing the n⁺-type high concentration impurity region 20 in the substrate 30 below the pad electrode 77, it is possible to increase the impurity concentration below the pad electrode 77 to a sufficiently high degree (the species of ion is ²⁹Si⁺, and the concentration is 1-5×10¹⁸ cm⁻³) unlike a surface of a substrate not doped with an impurity (which is semi-insulating and has a resistance value of the substrate equal to or above 1×10⁷ Ωcm). In this way, the pad electrode 77 is electrically isolated from the substrate 30, and a depletion layer does not extend form the pad electrode 77 toward the adjacent gate wiring 62, for example. That is, it is possible to provide the pad electrode 77 and the gate wiring 62 adjacent to each other with a substantially closer distance therebetween.

That is, by providing the high concentration impurity region 20 in the substrate 30 around the pad electrode 77, it is possible to ensure sufficient isolation even in the structure configured to provide the pad electrode 77 directly on the substrate 30.

Here, the structure of the high concentration impurity region 20 is the same as the epitaxial structure of the HEMT and includes the cap layer 37. The impurity concentration of this cap layer 37 mainly contributes to suppression of expansion of the depletion layer.

Moreover, the high concentration impurity region 20 is also disposed in the substrate near the gate wiring 62 bundling the comb teeth of the gate electrode 69 due to the same reason, and the high concentration impurity region 20 is connected to the gate wiring 62 in direct current mode. A part of the substrate 30 is isolated by the B+ implantation for insulation. Therefore high concentration impurity region 20 is formed in the substrate 30 below and around the gate wiring 62. The gate wiring 62 is made of gate metal layer 68 which is formed simultaneously with the gate electrode 69. That is, the cap layer 37 below the gate wiring 62 is removed by etching. The undoped AlGaAs layer 36 as the barrier layer is located below the gate wiring 62, and the high concentration impurity region 20 does not exist under the gate wiring 62 but exists only in the vicinity thereof In other words, the high concentration impurity region 20 provided with the gate wiring 62 is essentially the cap layer 37 in the vicinity of the gate wiring 62. Here, the distance between the gate wiring 62 and the cap layer 37 is about 0.3 μm, which is similar to the distance between the gate electrode 69 and the source region 38s and the distance between the gate electrode 69 and the drain region 38d. That is, even though the gate wiring 62 is physically separated from the cap layer 37 by about 0.3 μm, direct currents can run through the separation between the gate wiring 62 and the cap layer 37. This is termed a direct current mode. This structure prevents leakage of the high frequency signal from the gate wiring 62 to the substrate 30.

The same direct current configuration may be provided for the pad electrode 77. That is, as shown in FIG. 1D and further explained below, even though there is a separation between the pad electrode 77 and the high concentration impurity region 20, the separation is determined such that direct currents can still run between the pad electrode 77 and the high concentration impurity region 20.

Meanwhile, pad wiring 78 made of the pad metal layer 74 extends on nitride film 72 provided on the surface of the substrate 30 and connects the operating region 38 of the HEMT to the pad electrode 77.

Moreover, it is preferable to dispose the high concentration impurity region 20 also in the substrate 30 below the pad wiring 78 as shown in FIG. 1B. The high concentration impurity region 20 below the pad wiring 78 has floating potential, which is that no direct current potential is applied thereto. In a region where the pad wiring 78 for transmitting the high frequency analog signal is disposed, the nitride film 72 becomes a capacitive element, whereby the high frequency signal passes through the nitride film 72 and reaches the substrate. Accordingly, it is possible to prevent leakage of the high frequency signal by providing the high concentration impurity region 20 having the floating potential so as to block extension of the depletion layer.

By providing the high concentration impurity layer 20 below or around the gate wiring 62 or the pad wiring 78 in addition to the pad electrode 77, it is possible to enhance isolation more effectively.

As described above, by disposing the high concentration impurity region 20 below the pad electrode 77 for preventing leakage of the high frequency signal, it is possible to omit the nitride film below the pad electrode 77.

Moreover, the pad electrode 77 of this embodiment has the structure in which the pad metal layer 74 is directly contacted to the substrate 30. That is, instead of providing the gate metal layer 68 conventionally formed as the first pad electrode in the formation region for the pad electrode 77, the pad electrode 77 is formed solely by use of the pad metal layer 74. In this way, it is possible to prevent adverse effects to the pad electrode 77 due to hardening of the buried metal even in the structure configured to bury part of the gate electrode 69 in the operating region 38 to enhance the characteristics of the HEMT.

When there is no hardened metal layer, it is possible to prevent defects at the time of wire bonding and to suppress deterioration in yields and reliability because the pad metal layer 74 is sufficiently suitable for wire bonding.

Incidentally, FIGS. 1C and 1D are cross-sectional views showing other patterns of the high concentration impurity region 20 correspond to the line a-a of FIG. 1A. As shown in FIG. 1C, when the pad electrode 77 is directly connected to the high concentration impurity region 20, the high concentration impurity region 20 may be provided in the substrate 30 below the periphery of the pad electrode 77 so as to protrude out of the pad electrode 77.

Moreover, as shown in FIG. 1D, the high concentration impurity region 20 may be provided in the substrate 30 in the vicinity of the pad electrode 77 but away from the pad electrode 77. Specifically, the high concentration impurity region 20 is formed in the vicinity of the pad electrode 77 by isolation with the insulating region 45. It is possible to connect the high concentration impurity region 20 sufficiently to the pad electrode 77 in direct current mode through the insulating substrate (insulating region 45) by providing the space between the high concentration impurity region 20 and the pad electrode 77 in a range of about 0.1 μm to 5 μm.

Meanwhile, it is more effective to provide the high concentration impurity region 20 also in the vicinity of the gate wiring 62 so as to be connected to the gate wiring 62. The same is true for the vicinity of the pad wiring 78. In FIG. 1D; the high concentration impurity regions 20 for connecting the pad electrode 77 and the gate wiring 62 in direct current mode are respectively disposed as the high concentration impurity regions in the vicinity of the pad wiring 78. In the case of a pattern in which the pad wiring 78 is not disposed adjacently to the pad electrode 77 or the gate wiring 62, the high concentration impurity region 20 having the floating potential may be disposed below the pad wiring 78.

Here, the high concentration impurity region 20 is the region for preventing leakage of the high frequency signal between the pad electrode 77 and another formation element (such as the gate wiring 62, the pad wiring 78 or the operating region 38). Accordingly, it is only necessary that the high concentration impurity region 20 is disposed between the pad electrode 77 and another formation element which is disposed adjacent to the pad electrode 77.

For example, as shown in FIGS. 1B and 1C, it is effective for enhancing isolation if the high concentration impurity region 20 is formed in the substrate 30 below the entire surface of (or in the vicinity of) the pad electrode 77 so as to contact directly to the pad electrode 77. Meanwhile, as shown in FIG. 1D, when the high concentration impurity region 20 is disposed in a small space in the vicinity of the pad electrode 77 and between the pad electrode 77 and any of the pad wiring 78 and the gate wiring 62, it is possible to suppress leakage of the high frequency signal with such a small space.

This embodiment is applicable similarly to a different epitaxial structure of the HEMT including additional alternation of AlGaAs layers and GaAs layers between the cap layer 37 and the barrier layer 36 or including an InGaP layer.

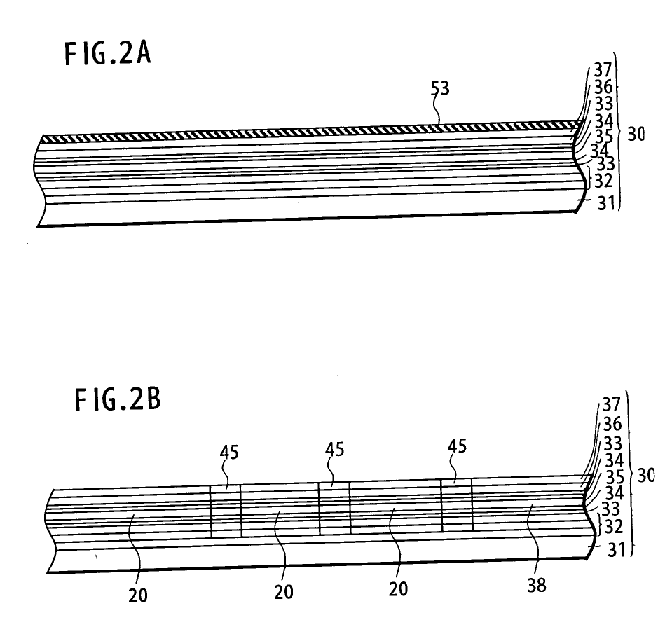

A manufacturing method of a compound semiconductor device according to an embodiment of the invention will be described with reference to FIG. 2A to FIG. 5C based on the structure shown in FIG. 1B as an example.

A method of manufacturing a compound semiconductor device according to the embodiment of the invention includes the steps of growing epitaxial layers to be an operating region on a initial compound semiconductor substrate and forming a high concentration impurity region in the substrate around or below a pad electrode formation region, forming first source and first drain electrodes by evaporating an ohmic metal layer being a first metal layer onto the operating region, forming a gate electrode by evaporating a gate metal layer being a second metal layer partially onto the operating region, forming second source and second drain electrodes and a pad electrode for connecting the high concentration impurity region in direct current mode by evaporating a pad metal layer being a third metal layer onto surfaces of the first source and first drain electrodes and surface of the substrate in the pad electrode formation region, and bonding a bonding wire onto the pad electrode.

First step (FIGS. 2A and 2B): The step of growing epitaxial layers constituting an operating region on a initial compound semiconductor substrate and forming a high concentration impurity region in the substrate around or below a pad electrode forming region.

Firstly, as shown in FIG. 2A, a substrate 30 including growing of epitaxial layers to be a buffer layer, electron supply layers, a channel layer, a barrier layer, and a cap layer is prepared.

Specifically, the substrate 30 is formed by growing an undoped buffer layer 32 on a semi-insulating initial GaAs substrate 31. The buffer layer 32 is often formed with a plurality of layers, and has a thickness of several thousand angstroms. The buffer layer 32 is a high-resistance layer with no addition of an impurity.

An n⁺-type AlGaAs layer 33 to be the electron supply layer, a spacer layer 34, an undoped InGaAs layer 35 to be the electron transit layer, the spacer layer 34, and an n⁺-type AlGaAs layer 33 to be the other electron supply layer are sequentially grown on the buffer layer 32. An n-type impurity (such as Si) is added to each of the electron supply layer 33 in a range of about 2 to 4×10¹⁸ cm⁻³.

To ensure predetermined breakdown voltage and pinch-off voltage, an undoped AlGaAs layer to be a barrier layer 36 is grown on the electron supply layer 33. Moreover, an n+-type GaAs layer 37 to be a cap layer 37 is grown as the uppermost layer.

The entire surface of the substrate 30 is covered with silicon nitride film 53 for annealing in a thickness of about 400 Å to 500 Å, and an alignment mark (not shown) is formed by etching the substrate 30 either on the outer periphery of a chip or a given region of a mask.

Thereafter, as shown in FIG. 2B, a new resist layer (not shown) is formed, and then a photolithography process for selectively forming a opening of the resist layer (not shown) in a formation region of an insulating region 45 is performed in order to form the insulating region 45. Then, ions of an impurity (such as B⁺) are implanted on the surface of the substrate 30 at a dose of 1×10¹³ cm⁻² and at an acceleration voltage of about 100 KeV while using this resist layer as a mask.

Thereafter, the resist layer is removed and activation annealing (at 500° C. for approximately 30 seconds) is performed. In this way, the insulating region 45 is formed while isolating a operating region 38 and a high concentration impurity region 20. Subsequently, nitride film 53 on the surface is entirely removed.

The high concentration impurity regions 20 are formed in the substrate below the respective formation regions for pad electrode 77, gate wiring 62, and pad wiring 78. In the subsequent step, the pad electrode 77 and the gate wiring 62 are connected to the high concentration impurity regions 20 formed in the substrate below the formation regions thereof are connected in direct current mode, respectively. On the contrary, the pad wiring 78 and the high concentration impurity region 20 formed in the substrate below the formation region thereof are insulated each other by the nitride film and are not therefore connected in direct current mode. That is, the high concentration impurity region 20 provided for the pad wiring 78 is formed as the high concentration impurity region 20 having the floating potential to which no direct current potential is applied.

By use of the high concentration impurity regions 20, it is possible to suppress a depletion layer extending from the pad electrode 77 (as well as the gate wiring 62 and the pad wiring 78) formed in the subsequent step toward the substrate, and thereby to prevent leakage of the high frequency signal.

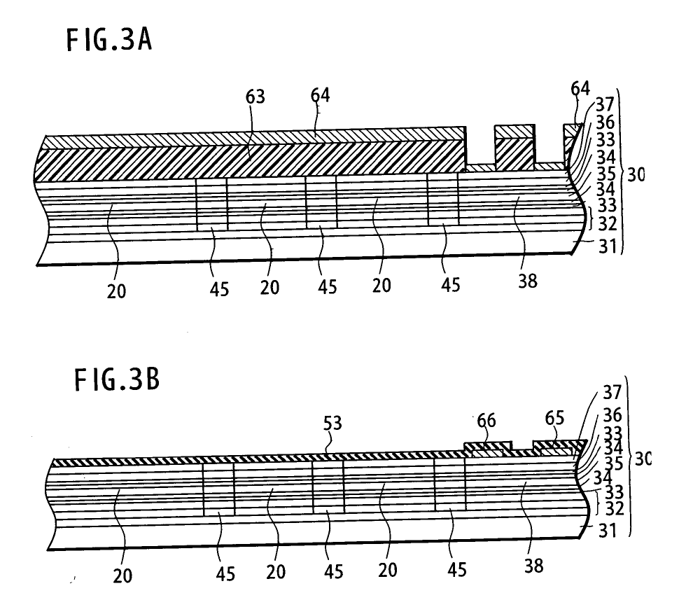

Second step (FIGS. 3A and 3B): The step of forming first source and first drain electrodes by evaporating an ohmic metal layer being a first metal layer onto the operating region.

New resist layer 63 is formed as shown in FIG. 3A. Then, a photolithography process is performed to selectively form openings of formation regions for first source electrode 65 and first drain electrode 66. In this way, as the operating region 38 is exposed, three layers of AuGe/Ni/Au collectively constituting ohmic metal layer 64 are sequentially deposited by vacuum evaporation.

Thereafter, as shown in FIG. 3B, the resist layer 63 is removed and the first source electrode 65 and the first drain electrode 66 contacting the operating region 38 are left over by the lift-off method. Subsequently, ohmic junctions between the surface of the operating region 38 and the first source electrode 65 as well as the first drain electrode 66 are formed by an alloying heat treatment. Moreover, the nitride film 53 is again formed on the entire surface of the resultant structure.

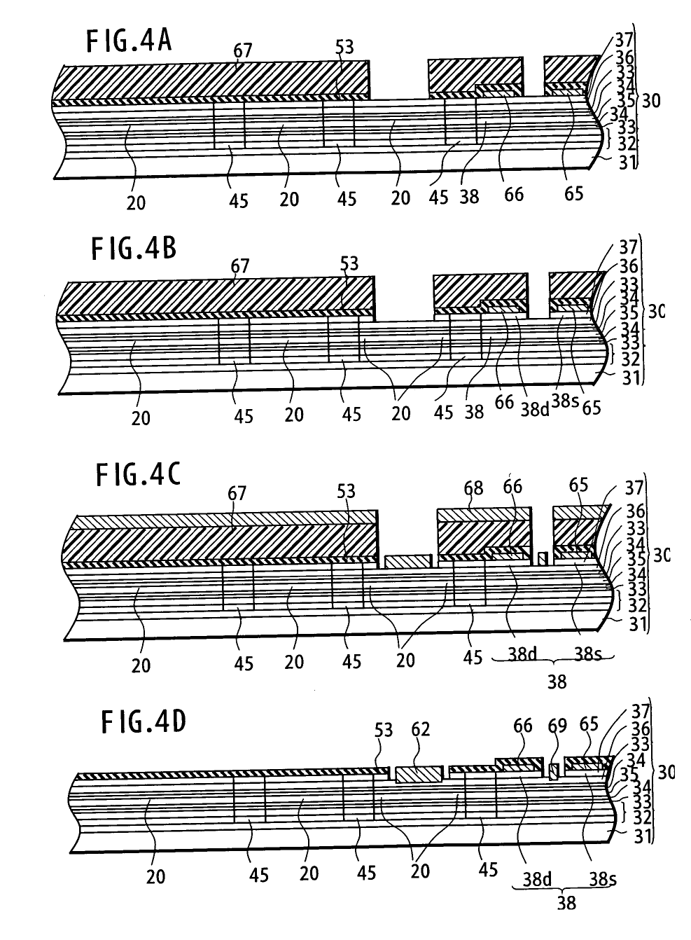

Third step (FIGS. 4A to 4D): The step of forming a gate electrode by evaporating a gate metal layer being a second metal layer partially onto the operating region.

Firstly, new resist layer 67 is formed as shown in FIG. 4A. Then, a photolithography process is performed to selectively form openings of formation regions for the gate electrode 69 and the gate wiring 62. The nitride film 53 exposed in the formation regions for the gate electrode 69 and the gate wiring 62 is subjected to dry etching. Accordingly, the surface of the substrate 30 (the cap layer 37) in the respective formation regions for the gate electrode 69 and the gate wiring 62 is exposed.

Next, as shown in FIG. 4B, the exposed cap layer 37 is removed by etching while leaving the resist layer 67. Accordingly, the barrier layer 36 for forming the Schottky junction with a gate metal layer 68 is exposed. Although detailed illustration is omitted herein, the cap layer 37 is subjected to side etching at a distance of 0.3 μm from the gate electrode to be formed later. A source region 38s and a drain region 38d are formed by etching the portion of the cap layer 37 corresponding to the gate electrode. That is, the source region 38s and the drain region 38d are formed automatically in the process step of forming the gate electrode.

Then, as shown in FIG. 4C, two layers of Pt/Mo collectively constituting the gate metal layer 68 are sequentially deposited by vacuum evaporation as electrodes on the second layer.

Thereafter as shown in FIG. 4D, the resist layer 67 is removed by the lift-off method. Then a heat treatment is performed to bury Pt of the lowermost layer of the gate metal layer 68. In this way, part of the gate electrode 69 is buried in part of the barrier layer 36 of the operating region 38 while maintaining the Schottky junction with the substrate. Here, the barrier layer 36 is grown thickly to obtain desired HEMT characteristic in consideration of the depth of the gate electrode 69 to be buried.

In this way, an edge on the drain side of a cross section of the gate electrode 69 is formed into a round shape (and an edge on the source side as well), and electric field strength between the gate electrode and the drain electrode is reduced. As relevant to such reduction, it is possible to increase donor impurity concentration of the n⁺-type AlGaAs layer 33 as the electron supply layer. As a result, the number of electrons flowing in the undoped InGaAs layer 35 to be the electron transimtting layer is increased. In this way, there are advantages of substantially improving current density, channel resistance, and a high frequency distortion characteristic. Here, the gate electrode 69 is connected to the cap layer 37 to be the source region 38s and the drain region 38d in direct current mode. Similarly, the gate wiring 62 is also buried in the surface of the substrate 30 and is connected to the high concentration impurity region 20 in the vicinity in direct current mode. Although part of the buried portion is hardened, such hardening causes no problem because any external force such as wire bonding is not applied to the gate wiring 62.

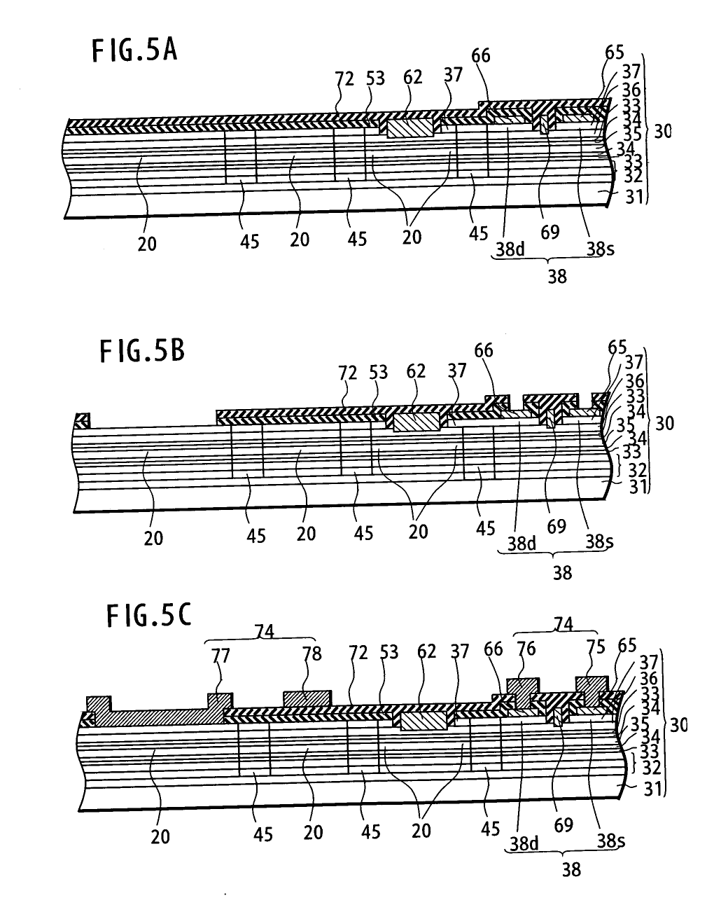

Fourth step (FIGS. 5A to 5C): The step of forming second source and second drain electrodes and a pad electrode for connecting the high concentration impurity region in direct current mode by evaporating a pad metal layer as electrodes of the third layer onto surfaces of the first source and first drain electrodes and surface of the substrate in the pad electrode formation region, and bonding a bonding wire onto the pad electrode formation region.

As shown in FIG. 5A, after forming the gate electrode 69 and the gate wiring 62, the surface of the substrate 30 is covered with passivation film 72 made of a silicon nitride film in order to protect the operating region 38 around the gate electrode 69.

Next, as shown in FIG. 5B, a resist layer (not shown) is provided on the passivation film 72, and a photolithography process is performed. Openings are selectively formed on the resist (not shown) corresponding to contact portions of the first source electrode 65 and the first drain electrode 66, and the passivation film 72 and the nitride film 53 at the portions are subjected to dry etching.

Simultaneously, an opening is selectively formed in the resist corresponding to the pad electrode 77 formation region, and the passivation film 72 and the nitride film 53 at the portion are subjected to dry etching. Then, the resist layer is removed.

In this way, contact holes are formed in the passivation film 72 on the first source electrode 65 and on the first drain electrode 66, and the surface of the substrate 30 (the cap layer 37) in the pad electrode 77 formation region is exposed.

Moreover, as shown in FIG. 5C, a new resist layer (not shown) is coated on the entire surface of the substrate 30. Then, a photolithography process is performed. In this photolithography process, openings are selectively formed in the resist layer above respective formation regions for second source electrode 75, second drain electrode 76, the pad electrode 77, and the pad wiring 78.

Subsequently, three layers of Ti/Pt/Au collectively to be pad metal layer 74 as electrodes of the third layer are sequentially deposited by vacuum evaporation. After removing the resist layer, the second source electrode 75 and the second drain electrode 76 for contacting the first source electrode 65 and the first drain electrode 66 are formed by the lift-off method.

Simultaneously, the pad electrode 77 is formed so as to be contacted directly to the substrate 30, and then the pad wiring 78 in a given pattern is formed on the nitride film 72. In FIG. 5C, the pad electrode 77 directly contacts the high concentration impurity region 20 formed in the substrate 30 below the entire surface of the pad electrode 77, and is connected to the high concentration impurity region 20 in direct current mode. The nitride films 72 and 53 are disposed below the pad wiring 78. For this reason, when the high frequency signal passes through the pad wiring 78, the nitride films become capacitive elements and the high frequency signal leaks out to the substrate. However, by disposing the high concentration impurity region 20 below the pad wiring 78 as described in this embodiment, it is possible to prevent leakage of the high frequency signal without connection in direct current mode.

Fifth step (FIG. 1B): The step of bonding a bonding wire onto the pad electrode.

After completion of the above-described wafer process, the compound semiconductor switching circuit device is subjected to an assembly process for assembly. The semiconductor wafer is diced and separated into individual semiconductor chips. After bonding each semiconductor chip to a frame (not shown), the pad electrode 77 of the semiconductor chip is connected to a given lead (not shown) with bonding wire 80. A gold thin wire is used as the bonding wire 80, and connection is achieved by publicly known ball bonding. Thereafter, resin packaging is performed by transfer molding.

In this embodiment, the pad electrode 77 is solely made of the pad metal layer 74. That is, the gate metal layer 68 is not disposed therebelow unlike the conventional art. Accordingly, when forming the FET of the buried gate electrode structure, the pad electrode 77 is not adversely affected even if part of the gate metal layer is hardened. Since the pad metal layer 74 is made of a material suitable for wire boding, it is possible to achieve fine bonding when the hardened metal layer is not disposed.

Here, by changing the pattern for forming the insulating region 45 in the first step, it is possible to form the high concentration impurity region 20 which contacts the pad electrode 77 directly in the vicinity of the pad electrode 77 as shown in FIG. 1C. Moreover, the high concentration impurity region 20 shown in FIG. 1D, which is connected in direct current mode and disposed in the vicinity of the pad electrode 77 but away from the pad electrode 77, can be also formed by changing the pattern of the insulating region 45.

This embodiment is applicable similarly to a different epitaxial structure of the HEMT including additional alternation of AlGaAs layers and GaAs layers between the cap layer 37 and the barrier layer 36 or including an InGaP layer.

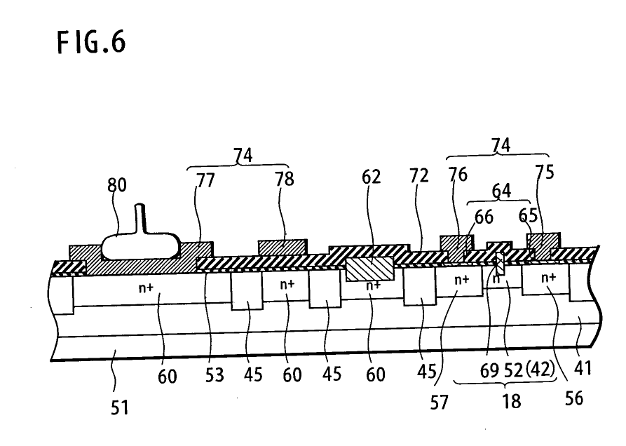

Next, a second embodiment of the present invention will be described with reference to FIG. 6 to FIG. 8C. The second embodiment concerns a FET in which a substrate is made of a GaAs substrate and an operating region is formed by growing epitaxial layers on the GaAs initial substrate.

Here, the structure of the substrate of this embodiment is different from the HEMT in the first embodiment. However, pad electrode and wirings have substantially the same configurations as those in the first embodiment. Accordingly, detailed description will be omitted herein in terms of overlapping parts.

As shown in FIG. 6, the substrate is formed by providing buffer layer 41 for suppressing leakage on undoped compound semiconductor substrate 51 in a thickness of about 6000 Å and then growing n-type epitaxial layer 42 thereon. The buffer layer 41 is either an undoped epitaxial layer or an epitaxial layer introducing an impurity for preventing substrate leakage, and the n-type epitaxial layer 42 (2×10¹⁷ cm⁻³ and 1100 Å) is grown thereon. Here, the n-type epitaxial layer 42 is the region to be channel layer 52.

That is, operating region 18 in the second embodiment is formed of source region 56 and drain region 57 formed by implanting ions of an n-type impurity (²⁹Si⁺) into the n-type epitaxial layer 42, and of channel layer 52 between the both regions.

Then, ions of the n-type impurity (²⁹Si⁺) are also implanted below the pad electrode 77, pad wiring 78, and gate wiring 62 to provide high concentration impurity region 60.

First source electrode 65 and first drain electrode 66 made of an ohmic metal layer 64 (AuGe/Ni/Au) of a first layer are provided on the source region 56 and the drain region 57.

Meanwhile, gate electrode 69 is provided by evaporating a gate metal layer (Pt/Mo) of a second metal layer to the channel layer 52. Moreover, second source electrode 75 and second drain electrode 76 made of pad metal layer 74 (Ti/Pt/Au) of a third metal layer are provided on the first source electrode 65 and the first drain electrode 66. Note that FIG. 6 shows one set of the source electrodes 65 and 75, drain electrodes 66 and 76, and the gate electrode 69. However, in reality, the operating region 38 is formed by means of arranging a plurality of sets adjacently to one another while using the source region 38s or the drain region 38d in common (as similar to the operating region 38 in FIG. 1A).

Moreover, the gate electrode 69 is formed as a buried gate electrode which is partially buried in the channel layer 52 while maintaining Schottky junction with the substrate.

The pad electrode 77 is provided by contacting pad metal layer 74 extending from the FET directly to the surface of the substrate. The high concentration impurity region 60 is provided below the pad electrode 77 so as to contact the entire surface of the pad electrode 77. The high concentration impurity region 60 has impurity concentration equal to or above 1×10¹⁷ cm⁻³, and is connected to the pad electrode 77 for transmitting a high frequency analog signal in direct current mode, thereby suppressing a depletion layer extending from the pad electrode 77 toward the substrate.

As shown in FIG. 6, the high concentration impurity region 60 is more effective for enhancing isolation when disposed below the pad wiring 78 and the gate wiring 62.

Meanwhile, the high concentration impurity region 60 may be provided in the substrate below the vicinity of the pad electrode 77 and connected directly to the pad electrode 77 as shown in FIG. 1C. Alternatively, as shown in FIG. 1D, the high concentration impurity region 60 may be provided in the substrate in the vicinity of the pad electrode 77 but away from the pad electrode 77. In this case, it is possible to connect the high concentration impurity region 60 sufficiently to the pad electrode 77 in direct current mode through the substrate by providing a space between the high concentration impurity region 60 and the pad electrode 77 in a range of about 0.1 μm to 5 μm.

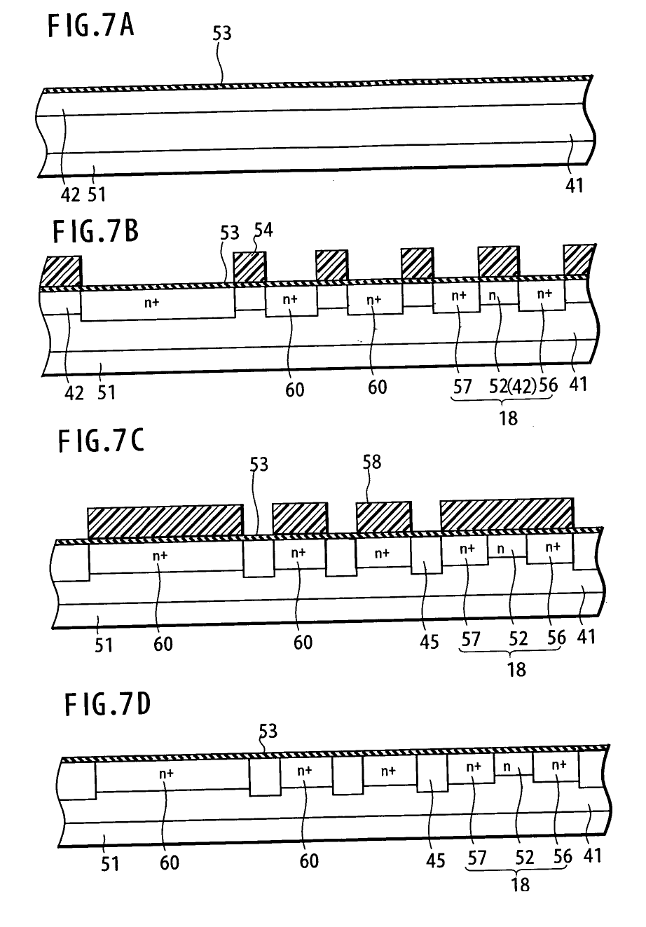

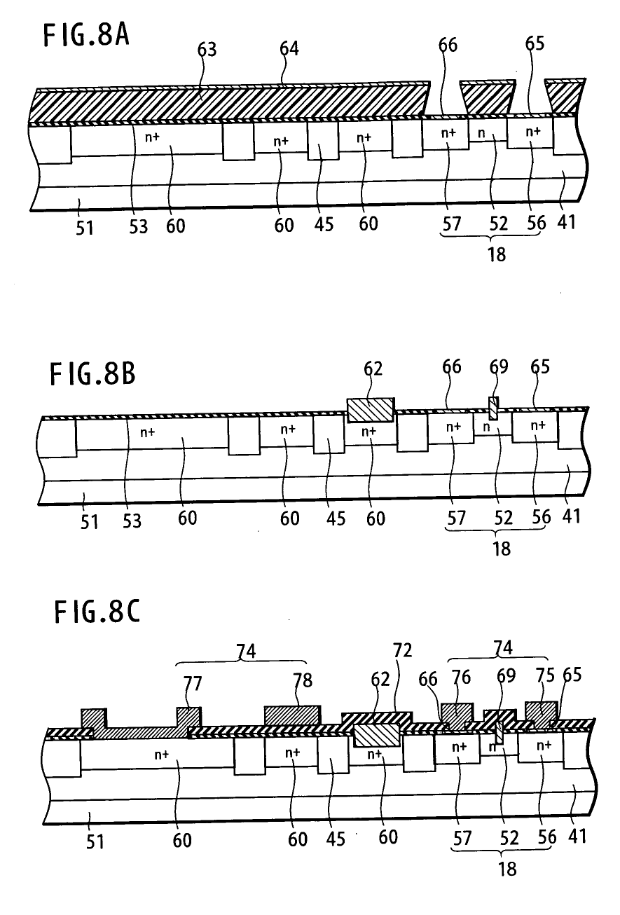

FIGS. 7A to 8C are cross-sectional views for describing a method of manufacturing a compound semiconductor device according to the second embodiment.

First step (FIGS. 7A to 7D): Firstly, as shown in FIG. 7A, buffer layer 41 for suppressing leakage is provided on undoped initial compound semiconductor substrate 51 made of GaAs and the like in a thickness of about 6000 Å. This buffer layer 41 is either an undoped epitaxial layer or an epitaxial layer introducing an impurity for preventing substrate leakage. Then, n-type epitaxial layer 42 is grown thereon (2×10¹⁷ cm⁻³ and 1100 Å). Thereafter, the entire surface of the resultant structure is covered with annealing silicon nitride film 53 in a thickness of about 500 Åto 600 Å.

Next, as shown in FIG. 7B, resist layer 54 is provided on the entire surface of the resultant structure, and a photolithography process is performed to selectively form openings in the resist layer 54 on respective formation regions for source region 56, drain region 57, pad electrode 77, pad wiring 78, and gate wiring 62. Subsequently, ions of an n-type impurity (²⁹Si⁺) are implanted on the formation regions for source region 56, drain region 57 and the surface of the substrate below the pad electrode 77, the pad wiring 78, and the gate wiring 62 while using the resist layer 54 as a mask. In this way, the n⁺-type source region 56 and drain region 57 are formed. Simultaneously, high concentration impurity region 60 (having impurity concentration equal to or above 1×10¹⁷ cm⁻³) is formed in the surface of the substrate below the pad electrode 77, the pad wiring 78, and the gate wiring 62.

The source region 56 and the drain region 57 are provided adjacently to channel layer 52 made of the n-type epitaxial layer 42, thereby constituting operating region 18.

When the n-type epitaxial layer 42 is used as the channel layer 52, the impurity concentration of the channel layer becomes uniform in terms of the depth direction as compared to the case of forming the channel layer by ion implantation.

Next, insulating layer 45 is formed in the whole region except the impurity regions such as the operating region 18 and the high concentration impurity region 60 as shown in FIG. 7C.

In the second embodiment, the operating region 18 and the high concentration impurity region 60, which are formed by providing the n+-type impurity regions selectively in the n-type epitaxial layer 42, need to be isolated from one another. That is, new resist layer 58 is provided on the entire surface, and then a photolithography process is performed to selectively leave the resist layer 58 on the high concentration impurity region 60 and the operating region 18 while forming openings for the rest of portions. Subsequently, ions of an impurity (such as B⁺ or H⁺) are implanted on the surface of the GaAs substrate at a dose of 1×10¹³ cm⁻² and at an acceleration voltage of about 100 KeV while using this resist layer 58 as a mask.

Thereafter, the resist layer 58 is removed and activation annealing is performed as shown in FIG. 7D. In this way, the source and drain regions 56 and 57 and the high concentration impurity region 60 are activated, and the insulating region 45 for isolating the operating region 18 from the high concentration impurity region 60 is formed. As described previously, this insulating region 45 does not have electrically complete insulation characteristics, but is the epitaxial layer to which ions of the impurity are implanted.

FIGS. 8A to 8C describe second to fourth steps.

Firstly, first source electrode 65 and first drain electrode 66 are formed in the second step which is similar to the first embodiment (FIG. 8A). Then, gate electrode 69 and the gate wiring 62 are formed in the third step. The gate electrode 69 is partially buried in the surface of the substrate while maintaining Schottky junction with the channel layer. Meanwhile, the gate wiring 62 is partially buried in the surface of the substrate as well. Since no gate metal layer is formed in the formation region for the pad electrode 77, nothing is buried in the region of pad electrode 77 (FIG. 8B).

Then, in the fourth step, the formation regions for the pad electrode 77 and the pad wiring 78 are selectively exposed from a resist in a photolithography process as shown in FIG. 8C, and then pad metal layer 74 is evaporated on the entire surface of the resultant structure. The pad electrode 77 and the pad wiring 78 are formed by the lift-off method. The pad electrode 77 is connected to the high concentration impurity region 60 in direct current mode, and is contacted directly to the substrate. That is, the pad electrode 77 is solely made of the pad metal layer 74. Accordingly, even in the case of the buried gate electrode structure for enhancing the FET characteristics, it is possible to suppress defects at the time of wire bonding.

The pad wiring 78 is formed on nitride film 72 in a desired pattern. Moreover, second source electrode 75 and second drain electrode 76 made of the pad metal layer 74 are simultaneously formed.

Then, a bonding wire is bonded in a fifth step to obtain the final structure shown in FIG. 6.

Here, the pattern of the high concentration impurity region 60 connected to the pad electrode 77 in direct current mode, and the pattern of the high concentration impurity region 60 provided below the gate wiring 62 and the pad wiring 78 can be appropriately combined depending on integration patterns.

In this way, the embodiment of the present invention is applicable not only to the HEMT but also to a FET similarly in which an operating region is formed by growing n-type epitaxial layers to be a channel layer on a GaAs initial substrate. The FET having the epitaxial layer as the channel layer has more advantages in terms of characteristics as compared to an FET having a channel layer formed by ion implantation. Particularly, in the case of an FET to be adopted for a switching circuit, it is possible to increase maximum linear input power. Moreover, at the same pinch-off voltage and at the same saturation drain current Idss, it is possible to reduce a gate width. Accordingly, it is possible to reduce parasitic capacitance, to suppress leakage of high frequency signals, and to enhance isolation. Moreover, in addition to the use for switches, a FET used for an amplifier circuit, for example, has higher mutual conductance gm at the same saturation drain current Idss. Such a FET has an advantage of capability of enhancing gain of amplifier.

The following effects are obtained by the embodiments of the present invention.

In the first place, the pad electrode is formed solely by use of the pad metal layer instead of disposing the gate metal layer at the pad electrode portion. Therefore, in the case of a buried gate electrode structure, it is possible to prevent defects at the time of wire bonding of the pad electrode. Conventionally, the gate metal layer has been provided below the pad electrode. For this reason, part of the gate metal layer below the pad electrode has been buried and hardened, thereby leading to numerous defects at the time of wire bonding. However, according to the embodiment of the present invention, it is possible to avoid such defects and to enhance yields and reliability.

In the second place, since the high concentration impurity region is provided below the pad electrode so as to protrude out of the pad electrode, it is possible to suppress a depletion layer which extends from the pad electrode toward the substrate. That is, it is possible to ensure sufficient isolation even in the case of the structure without the nitride film as similar to the conventional technique.

In the third place, the high concentration impurity region may be separated from the pad electrode and provided in the substrate around the pad electrode. Accordingly, even in the structure configured to contact the pad electrode solely made of the pad metal layer directly to the substrate, it is possible to ensure isolation by small spaces between the respective formation elements.

In the fourth place, according to the manufacturing method of the embodiment of the present invention, it is possible to realize the pad electrode solely made of the pad metal layer without disposing the gate metal layer. Since the gate metal layer which is apt to be hardened by burying is not disposed, it is possible to suppress defects such as bonding defects at the time of bonding or gouges on the substrate. That is, it is possible to provide the method of manufacturing a compound semiconductor device capable of enhancing reliability and yields.

In the fifth place, it is possible to form the FET having the buried gate electrode without disposing the gate metal layer, which is hardened by being buried below the pad electrode. Therefore, it is possible to provide the method of manufacturing a compound semiconductor device capable of enhancing characteristics of the FET and furthermore suppressing defects at the time of bonding.

In the sixth place, since the high concentration impurity region is formed in the substrate below the pad electrode, it is possible to provide the method of manufacturing a compound semiconductor device capable of suppressing a depletion layer which extends from the pad electrode and enhancing isolation.

In the seventh place, the high concentration impurity region may be separated from the pad electrode and provided in the surface of the substrate around the pad electrode. Accordingly, even in the structure configured to contact the pad electrode solely made of the pad metal layer directly to the substrate, it is possible to realize the method of manufacturing a compound semiconductor device capable of ensuring isolation by small spaces between the respective formation elements.

In the eighth place, it is possible to realize a buried gate electrode structure having fine FET characteristics only by modifying a mask pattern to be used in a photoresist process for the gate metal layer, and further to avoid defects at the time of wire bonding. Therefore, it is possible to enhance reliability and to improve yields without increasing the number of processes.

In the ninth place, by forming the FET as a HEMT by growing a buffer layer, an electron supply layer, an electron transmitting layer, a barrier layer, and a cap layer, it is possible to achieve substantially lower ON resistance value as compared to a usual GaAs FET.

1. A compound semiconductor device comprising:
a compound semiconductor substrate;
a stack of semiconductor layers disposed on the substrate;
an operating region formed in the stack;
a source region and a drain region that are formed in the operating region;
a gate electrode made of a gate metal layer and in contact with the operating region;
a source electrode comprising a first source electrode made of an ohmic metal layer and in contact with the source region and a second source electrode made of a pad metal layer and disposed on the first source electrode;
a drain electrode comprising a first drain electrode made of the ohmic metal layer and in contact with the drain region and a second drain electrode made of the pad metal layer and disposed on the first drain electrode;
a pad electrode made of the pad metal layer and in contact with the stack; and
a conducting region formed in the stack and adjacent the pad electrode.

2. The compound semiconductor device of claim 1, wherein the gate electrode is partially buried in the stack.

3. The compound semiconductor device of claim 1, wherein the pad electrode is in contact with the conducting region, and part of the conducting region is not covered by the pad electrode.

4. The compound semiconductor device of claim 1, wherein the entire portion of the pad electrode is covered by the conducting region.

5. The compound semiconductor device of claim 1, wherein the pad electrode is separated from the conducting region so that a separation between the pad electrode and the conducting region is such that a current flow is maintained under an application of direct current.

6. The compound semiconductor device of claim 1, wherein the stack of the semiconductor layers comprises a buffer layer, an electron supply layer, an electron transmitting layer, a barrier layer and a cap layer.

7. The compound semiconductor device of claim 1, wherein the conducting region is configured to suppress an expansion of a depletion layer extending from the pad electrode.

8. The compound semiconductor device of claim 1, wherein the pad electrode is configured to transmit a high frequency analog signal.

9. The compound semiconductor device of claim 1, wherein an impurity concentration of the conducting region is 1×10¹⁷ cm⁻³ or higher.

10. A method of manufacturing a compound semiconductor device comprising:
providing a compound semiconductor substrate;
forming a stack of semiconductor layers on the substrate;
forming a conducting region and an operating region in the stack;
forming a gate electrode made of a first metal on the operating region;
forming a pad electrode made of a second metal so that the second metal is in contact with the stack, the pad electrode being adjacent the conducting region; and
bonding a bonding wire to the pad electrode.

11. The method of claim 10, wherein the pad electrode is formed so that the pad electrode is in contact with the conducting region and part of the conducting region is not covered by the pad electrode.

12. The method of claim 10, wherein the pad electrode is formed so that the pad electrode is separated from the conducting region so that a separation between the pad electrode and the conducting region is such that a current flow is maintained under an application of direct current.

13. The method of claim 10, wherein the forming of the gate electrode comprises depositing a film containing platinum and heating the substrate so that the gate electrode is buried partially in the operating region.

14. The method of claim 10, wherein the forming of the stack of semiconductor layers comprises depositing a buffer layer, an electron supply layer, an electron transmitting layer, a barrier layer and a cap layer.

15. The method claim 10, wherein an impurity concentration of the conducting region is 1×10¹⁷ cm⁻³ or higher.

16. A method of manufacturing a compound semiconductor device comprising:
providing a compound semiconductor substrate;
forming a stack of semiconductor layers on the substrate;
forming a conducting region and an operating region in the stack;
depositing a first metal layer on the stack so as to form a first source electrode and a first drain electrode in contact with the operating region;
depositing a second metal layer on the stack so as to from a gate electrode on the operating region;
depositing a third metal layer on the stack so as to form a second source electrode on the first source electrode, a second drain electrode on the first drain electrode and a pad electrode that is in contact with the stack and adjacent the conducting region; and
bonding a bonding wire to the pad electrode.

17. The method of claim 16, wherein the pad electrode is formed so that the pad electrode is in contact with the conducting region and part of the conducting region is not covered by the pad electrode.

18. The method of claim 16, wherein the pad electrode is formed so that the pad electrode is separated from the conducting region so that a separation between the pad electrode and the conducting region is such that a current flow is maintained under an application of direct current.

19. The method of claim 16, wherein the forming of the gate electrode comprises depositing a film containing platinum and heating the substrate so that the gate electrode is buried partially in the operating region.

20. The method of claim 16, wherein the forming of the stack of semiconductor layers comprises depositing a buffer layer, an electron supply layer, an electron transmitting layer, a barrier layer and a cap layer.

21. The method claim 16, wherein an impurity concentration of the conducting region is 1×10¹⁷ cm⁻³ or higher.
